(19) United States
(12) Patent Application Publication
(10) Pub. No.: US 2003/0122615 A1
(43) Pub. Date: Jul. 3, 2003

(54) Improved Class BD Amplifier

(76) Inventor: Mr. Robert Terry Zeff, Ripon, CA (US)

(21) Appl. No.: 10/248,269

(22) Filed: Jan. 3, 2003

(51) Int. Cl. H03F 3/38

(52) U.S. Cl. 330/10

(57) ABSTRACT

### Abstract of Disclosure

An improved class BD (3-state) switching amplifier is provided requiring fewer power switching devices, and providing improved immunity to power-supply-induced distortion and greatly reduced notch distortion. Asymmetric gate drive delay circuitry produces time-coincident very short positive and negative drive pulses for very small signals, enabling linear performance down to zero input. The reference triangle wave is generated such that the positive amplitude of the triangle wave is modulated by the positive supply and the negative amplitude is modulated by the negative supply, eliminating to first order any supply-induced output distortion.

### Background of Invention

This invention relates to the field of electronics, and in more specifically to audio amplifiers and class D and BD amplifiers.

Electronic amplifiers are important building blocks for nearly every piece of consumer and military electronic equipment. Electronic amplifiers are key components of everything from home stereo equipment, to radios & televisions & VCRs, to personal computers & printers, to telephones. Important figures of merit for amplifiers in different applications include cost of implementation, efficiency, size, maximum power output, signal-to-noise ratio, radiated and conducted electromagnetic interference (EMI), linearity, maximum voltage or current output, and bandwidth. Among the applications for amplifiers in consumer electronics, audio amplifiers present some of the strictest demands in terms of signal-to-noise ratio, linearity, and power output. Along with high power output, efficiency also becomes important in audio amplifiers, because high efficiency means less heat to get rid of from the electronics when the amplifier is operating at high power output.

Since audio waveforms are fundamentally AC, audio amplifiers tend to be able to symmetrically amplify signals, providing at any instant either a positive or negative output. Amplifiers may be thought of as amplifying either voltage or current. Most of the examples in this text will discuss voltage amplification. Some may discuss current amplification, and others may discuss voltage-to-current amplification. Since any source driving an output impedance has both a Thevenin voltage source equivalent and a Norton current source equivalent, all examples given will be assumed to be readily transformable to either equivalent.

Linear amplifiers have typically been grouped into classes A and AB. The block diagram shown in figure 20 may be thought of as representing a wide range of electronic amplifiers. Voltage sources Vs1 & Vs2 provide the provide the positive and negative power supply rails for the amplifier. Control electronics CE controls upper conduction block UCB and lower conduction block LCB such that the output voltage Vout presented to the load is the desired scaled (amplified) version of the input voltage.

The voltage and current waveforms for class A and AB amplifiers are shown in figure 20. In class A amplifiers, for the full range of allowed input and output voltages, upper and lower conduction blocks UCB and LCB are both always conducting, though at any instant for a large output current, one will typically be conducting much more than the other. In class AB amplifiers, for low level signals, both conduction blocks UCB and LCB are conducting, but for large negative signals UCB shuts off and only LCB conducts (likewise for large positive signals LCB shuts off and only UCB conducts).

Ideally, in class both class A and AB amplifiers, the current waveforms of output conduction blocks UCB and LCB have no discontinuities, and the output waveform Vout is a scaled version of the input waveform Vin. In practice, many class AB amplifiers show some distortion in the output waveform when the output voltage transitions rapidly from one polarity to the other, because it takes some time to turn on the conduction block which has been off in the opposite polarity.

For typical waveforms, and typically running at a fraction of maximum output power, class A and AB amplifiers dissipate significantly more power in output conduction blocks UCB and LCB than they deliver into the load. Class A and AB amplifiers are thus very far from being efficient, and can require significant heat sinking and sometimes forced-air cooling for high-power designs.

To meet the demand for both high efficiency and high power, the state of the art in audio amplifiers has advanced over the years to include a variety of amplifiers which use switching and averaging techniques (rather than purely linear techniques) to accomplish amplification. Switching amplifiers typically create two-state or three-state pulse-width-modulated square waves, which, when averaged, are a good approximation to the desired amplified signal. Block diagrams of non-bridged and bridged two-state class D amplifiers are shown in figures 1 and 2, respectively.

In the non-bridged class D amplifier of figure 1, a reference triangle wave of a frequency well outside the audio range is provided to one input of a comparator, and an audio-bandwidth signal is provided to the other input. The amplitude of the reference triangle wave is chosen to be greater than the maximum allowable amplitude of the audio-bandwidth signal. The output of the comparator drives a two-state modulator, whose output is switched either to the positive supply rail or the negative supply rail, depending on the state of the comparator.

Filter inductor Lo and filter capacitor Co act as a two-pole low-pass filter to reduce the amplitude of the carrier-frequency ripple seen on the load resistor RL with respect to the audio-bandwidth component of the modulator output.

There are several disadvantages to the non-bridged class D amplifier topology shown in Figure 1. One major disadvantage is a phenomenon commonly referred to in the art as "supply pumping". To understand supply pumping, imagine for a moment that the non-bridged class D amplifier in figure 1 is amplifying a positive signal, so there is an average positive current IL flowing in the output inductor, because the modulator output is spending a higher percentage of time at the positive rail than at the negative rail. For the percentage of time that the modulator output does go to the negative rail, the average current IL in the inductor is flowing in the opposite direction to a current that the negative supply would supply into a passive load. Thus, the potential of the negative supply is driven more negative. Likewise, when a negative input signal is being amplified, the average current IL in the output inductor is negative, and drives current back into the positive supply for the smaller percentage of time that the modulator output is connected to the positive supply. Since power supplies are typically designed to source power but not sink power, the supply pumping phenomenon places a limit on how low a frequency input the amplifier can handle without creating an over-voltage condition on the output capacitors of its own power supplies.

The supply pumping problem also causes an output distortion problem, because in the absence of strong negative feedback (which is impractical to employ in switching amplifiers), any change in levels of the supplies causes a change in level of the output, so the output waveform itself becomes distorted from supply pumping.

In a Class A and AB audio amplifiers, distortions in the output can be reduced well through negative feedback applied around the amplifier. Unfortunately, in a class D amplifier, negative feedback around the entire amplifier is not practical for two reasons. The first reason is that the output LC filter creates so much phase shift that the feedback would not be stable. The second reason is that the large ripple at the modulation frequency causes problems in the feedback.

One solution to the supply pumping problem of the non-bridged class D amplifier of Figure 1 is to add in the actively switched balancing choke circuit of figure 15 across the rails of the supplies used to power the non-bridged class D amplifier of figure 1. Since one end of the balancing choke is connected to ground and the other end is switched between the positive and negative supplies at a 50% duty cycle, and since the average voltage across an inductor must be zero or its current would go to infinity, this topology forces exactly as much current to flow through the balancing choke as is needed to keep the positive and negative supplies at equal voltages above and below ground. The disadvantage of adding the balancing choke circuit is that it increases component count, cost, and power dissipation.

The bridged class D amplifier of figure 2 does not have the supply pumping problem of the non-bridged topology of figure 1, and it has the added advantage that it offers twice the peak output voltage to the load, however, it requires twice the number of power-switching components, and it has the additional disadvantage that both sides of its output are driven, so neither side may be connected to ground.

Both bridged and non-bridged class D amplifiers have the problem that as the signal level approaches zero, the ripple on the output approaches a maximum. Thus, the signal-to-ripple ratio approaches zero.

Three-state switching amplifiers (sometimes referred to as class BD amplifiers) overcome some of the limitations of class D amplifiers. In a class BD amplifier, the output of the modulator may be switched to ground as well as to the positive or negative rails. Examples of class BD amplifier topologies known in the field are shown in figures 1a and 2a. The ripple on the output of a class BD amplifier is much less than on a class D amplifier. Since the ripple on the output of a class BD amplifier is zero at full output and zero at zero output, the ripple vs. Vin and the % ripple vs. Vin are both always lower than class D ripple. Depending on the instantaneous output voltage, the ripple is anywhere from 6dB lower to (ideally) infinitely dB lower.

Another benefit of class BD designs over class D designs is that non-bridged class BD amplifiers do not exhibit the supply pumping problem that non-bridged class D designs exhibit.

Prior art accomplishes Class BD operation in several ways: In FIG. 1 (from U.S. Pat, #6,097,249), the positive and negative rails can be switched to ground via 10 or 12. The output can be switched via DPDT switch 11 to the output of switch 10 or switch 12. Various combinations of these switches yield the positive, negative, or ground state. These switches require two transistors each, thus this arrangement requires six switching devices. Passing the output current through three switches for each state increases complexity and reduces efficiency.

In FIG. 2 (from U.S. Pat, #6,097,249), the three output states are accomplished with combinations of DPDT switches 20 and 21. In this design the output current path always requires at least two switches. In addition, the power supply 23 is switching about ground at the modulation frequency 22. For full range audio amplifiers, this modulation frequency would likely be above 400kHz with harmonics extending above 10 MHz. While an idealized power supply might be thought of as "floating", real-life power supplies always have some stray capacitance from primary to secondary, so switching a power supply about ground at high frequency can cause serious problems.

In FIG. 3 (from U.S. Pat, #6,097,249), the power supply 36 is switched about ground at the output modulation frequency. The high frequency carrier (the frequency of the reference triangle wave) is present on the power transformer 30 for all input amplitudes and has a 50% duty cycle at zero output. FIG. 4 is a simplified illustration of FIG. 3 for high frequency AC current. The modulation frequency 44 is impressed upon the power supply transformer 42 at its secondary 43. Block 41 of FIG. 4 is a simple equivalent circuit showing the distributed primary-secondary capacitance 46. Block 51 represents an external component such as a CD player or receiver. The modulation of the power supply about ground effectively creates an AC signal with the frequency of the modulation and the amplitude of the power supply voltage. When the amplifier is hooked up to another audio component (such as a CD player) this large-amplitude, high-frequency signal is effectively in series with the stray capacitance from the power supply to ground, in series with a ground loop comprising the chassis of the amplifier & CD player, the ground side of audio cables, and the AC mains (or car battery & chassis)powering the audio equipment. This high frequency signal will cause serious EMI problems and would require complex filtering. All of the embodiments presented in the present invention do not switch the power supply, and thus avoid this problem.

In FIG. 5, the three output states are accomplished with what is commonly referred to as an H-Bridge. The output modulators 50 and 51 each require two switching devices. The output current passes through two switches at all times. Because this design requires bridging, the user of this amplifier does not have the flexibility of further bridging for high power mono output. Another disadvantage is that bridged designs preclude configurations where one output is ground.

One disadvantage (touched on earlier) of class D and BD amplifier designs known in the art is that any variation in supply voltage causes distortion in the output waveform. This is true because the demodulated output's open-loop magnitude is proportional to the power supply voltage for any particular input level. The output magnitude is:

$$Magnitude = K \cdot Supply Voltage \cdot \frac{Analog / N }{Carrier}$$

, where K represents the input gain.

The gain of the amplifier is proportional to the rail voltage. Thus noise and ripple on the supply rails cause distortion. Also, an imbalance between the positive and negative rails causes distortion because of unsymmetrical gains for the positive and negative output swings.

FIG. 6 (from U.S. Pat. # 6,356,151), shows a class D amplifier which utilizes a saw-tooth reference waveform, sensitivity of the output waveform to supply variations is minimized by making the amplitude of the saw-tooth waveform proportional to the supply voltage.

If the reference triangle wave magnitude is proportional to the supply voltage, the open-loop gain is:

$$Magnitude = K \cdot Analog / N$$

Thus distortion and supply dependant gain changes can be minimized if the magnitude of the reference triangle wave is proportional to the supply voltage.

In FIG. 7 (from U.S. Pat. # 6,356,151), a current source is comprised of transistor 40 and op-amp 41. The reference voltage for the current source is determined by the supply voltage 44 and the resistors divider 42 and 43. Capacitor 45 charges through current mirror 46. Device 47 discharges the capacitor on each clock cycle 48. The magnitude of the saw-tooth is now proportional to the supply voltage. This approach is applicable to a bridged, single supply design, but not to the present invention. Unfortunately, the circuitry disclosed in U.S. Pat. #6,356,151 specifically requires a saw-tooth waveform to implement this proportionality.

Besides supply-variation-induced distortion, another disadvantage of class BD amplifiers known in the art is that they have linearity problems for very small input signals. This problem is sometimes referred to as "notch distortion". The smaller the input signal, the narrower the output pulse would have to be so that, when averaged, the output signal would be correct. For small enough input signals, output signals are needed that have pulse widths narrower than the switching time of the electronics used to make the switches. Thus, below some input signal level, class BD amplifiers known in the art either produce very distorted output signals, or no output signal at all.

It is an object of the current invention to provide an improved class BD amplifier with reduced component count and cost. It is a further object of the current invention to provide an improved class BD amplifier drastically improved small-signal linearity, and ability to faithfully amplify much smaller signals (immunity to notch distortion). It is a further object of the present invention to provide an improved class BD amplifier with vastly less supply-level-induced output distortion.

### Summary of Invention

In one aspect, the present invention provides a reduced component count and parts cost by using an innovative switching topology

In a second aspect, the present invention provides improved linearity for small signals, by providing an innovative topology where at zero output, small positive and negative pulses are both present on the output of the modulator, thus allowing for linear amplification of signals down to the zero level.

In a third aspect, the present invention eliminates to first order any distortion on the output from supply voltage variation, by making a symmetrical reference triangle wave of a class BD amplifier be proportional to the supply voltage.

### Brief Description of Drawings

Figure 1: Non-bridged class D design from prior art.

Figure 2: Bridged class D design from prior art.

Figure 3: Prior art class D amplifier design where the power supply is switched about ground at the output modulation frequency.

Figure 4: Simplified schematic/block diagram showing the source of EMI in designs where the poser supply is switched about ground.

Figure 5: Bridged class D design from prior art.

Figure 6: Prior art class D amplifier using saw-tooth reference waveform.

Figure 7: Detailed prior art circuitry for reducing supply-variation-induced output distortion in class D amplifier with utilizing a saw-tooth reference waveform.

Figure 8: Circuitry for generating a power-supply-modulated reference triangle wave in a in a preferred embodiment of the present invention, providing drastic reduction in supply-induced output distortion.

Figure 9: Block/schematic diagram of a preferred embodiment of the present invention, including MOSFET gate drive circuitry and MOSFET output device topology.

Figure 10: Schematic of MOSFET gate drive circuitry for a preferred embodiment of the present invention, not including level-shifting and isolation circuitry.

Figure 11: Timing diagram showing phase relationship between drive waveforms and reference waveform in preferred embodiments of the present invention, at different input signal magnitudes.

Figure 12: Gate drive circuitry of a preferred embodiment of the present invention, including pulse stretching resistor-capacitor-diode networks.

Figure 13: Combination block diagram and schematic of a preferred embodiment of the present invention, showing details of notch-distortion-prevention circuitry and output switching topology.

Figure 14A: Block/schematic diagram of a preferred embodiment of the present invention.

Figure 14B: Block/schematic diagram of supply-voltage-modulated reference triangle wave generating circuitry in a preferred embodiment of the present invention.

Figure 15: Balancing choke circuitry used in some class D and BD designs to prevent supply pumping.

Figure 16: Block schematic diagram of the switching topology of the current invention.

Figure 17: Relationship between input analog signal, reference triangle wave, and output of modulator for a two-state class D amplifier.

Figure 18: Block diagram of Class A and Class AB amplifiers.

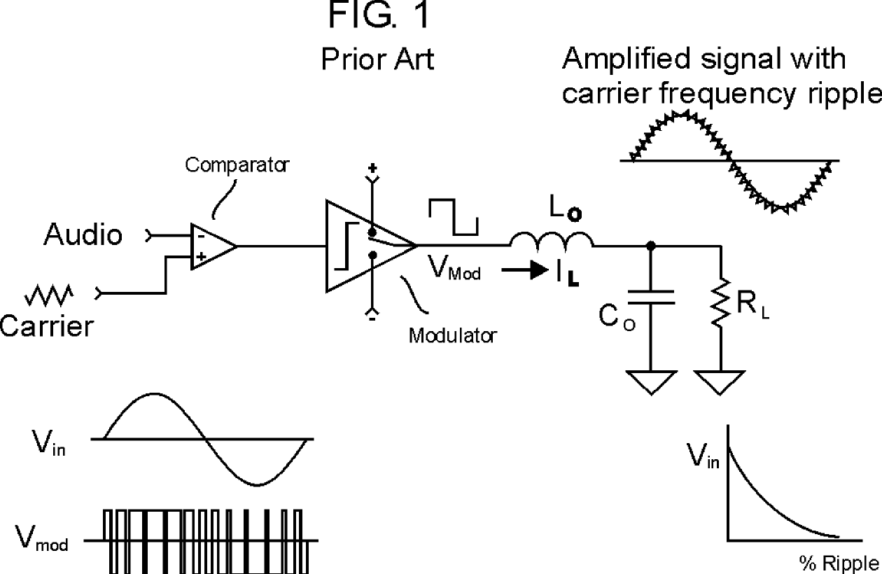

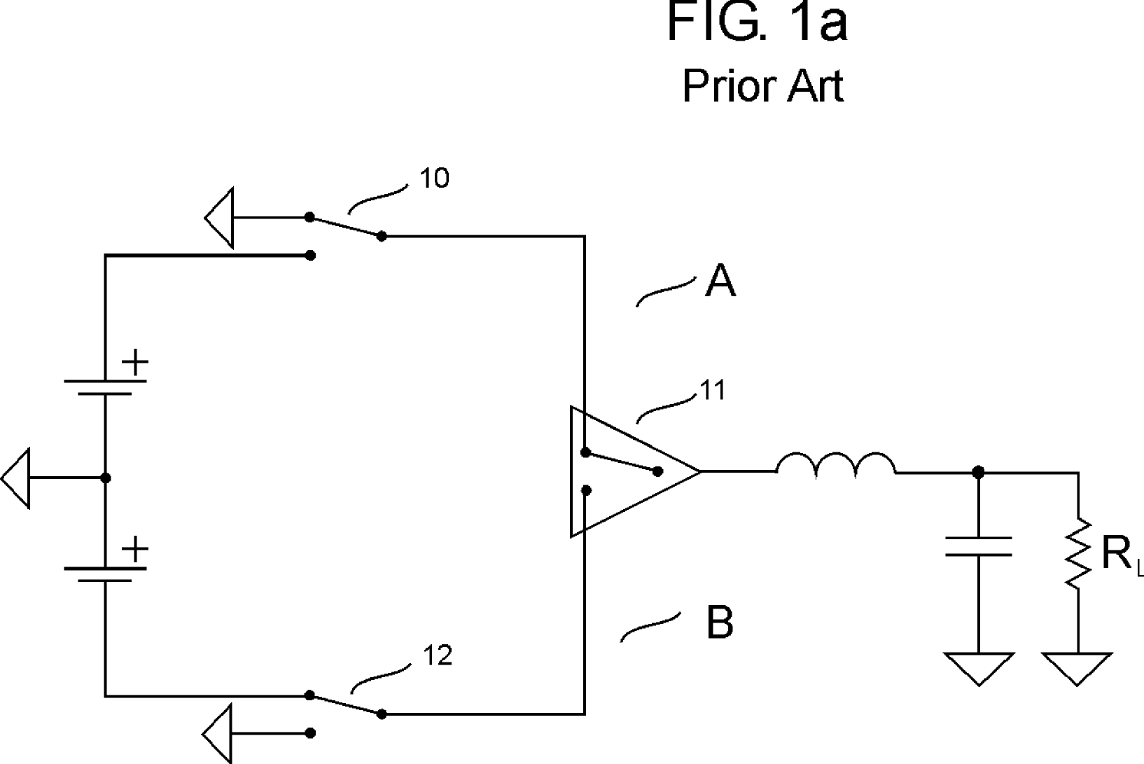

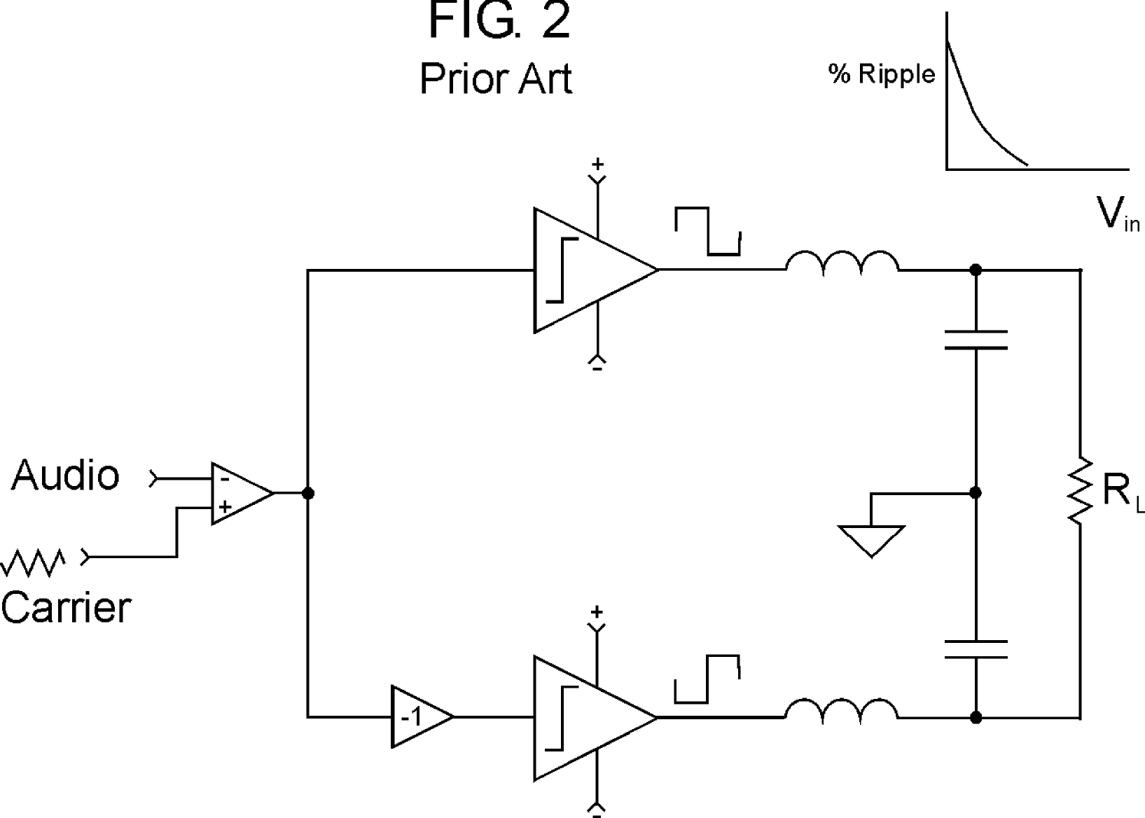

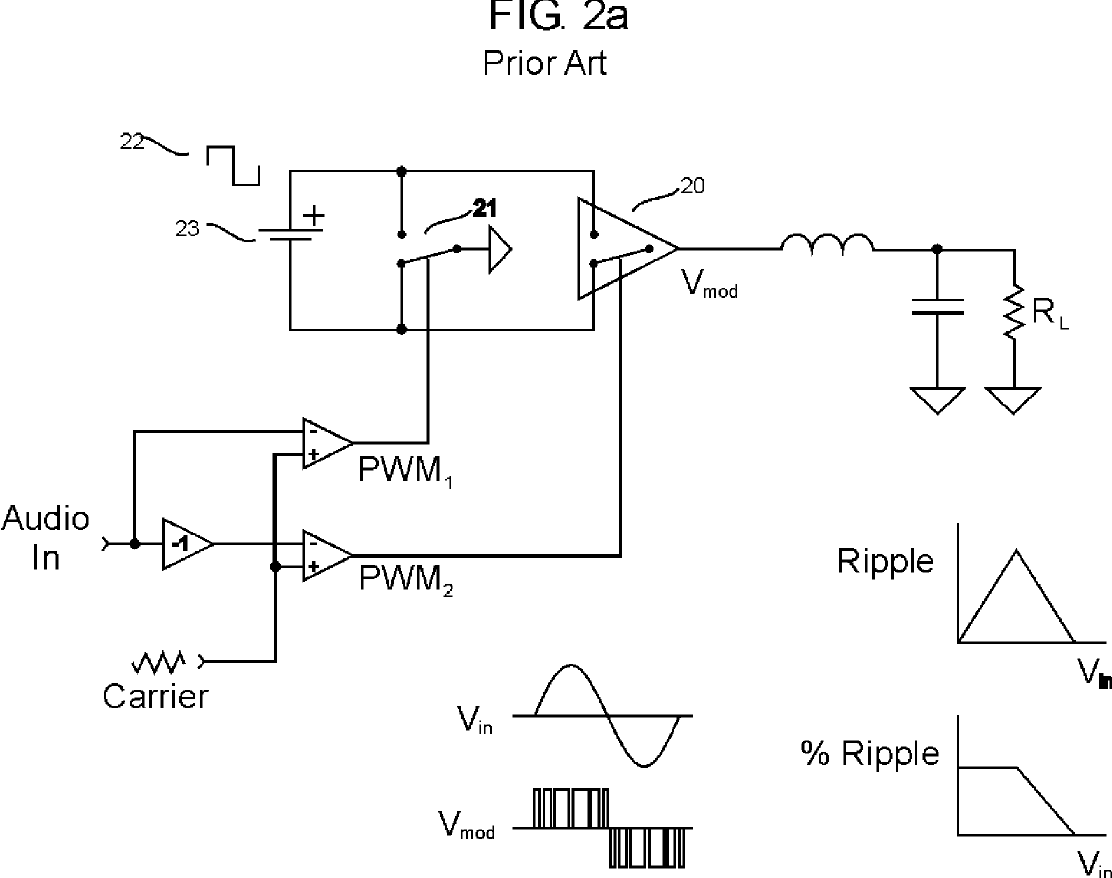

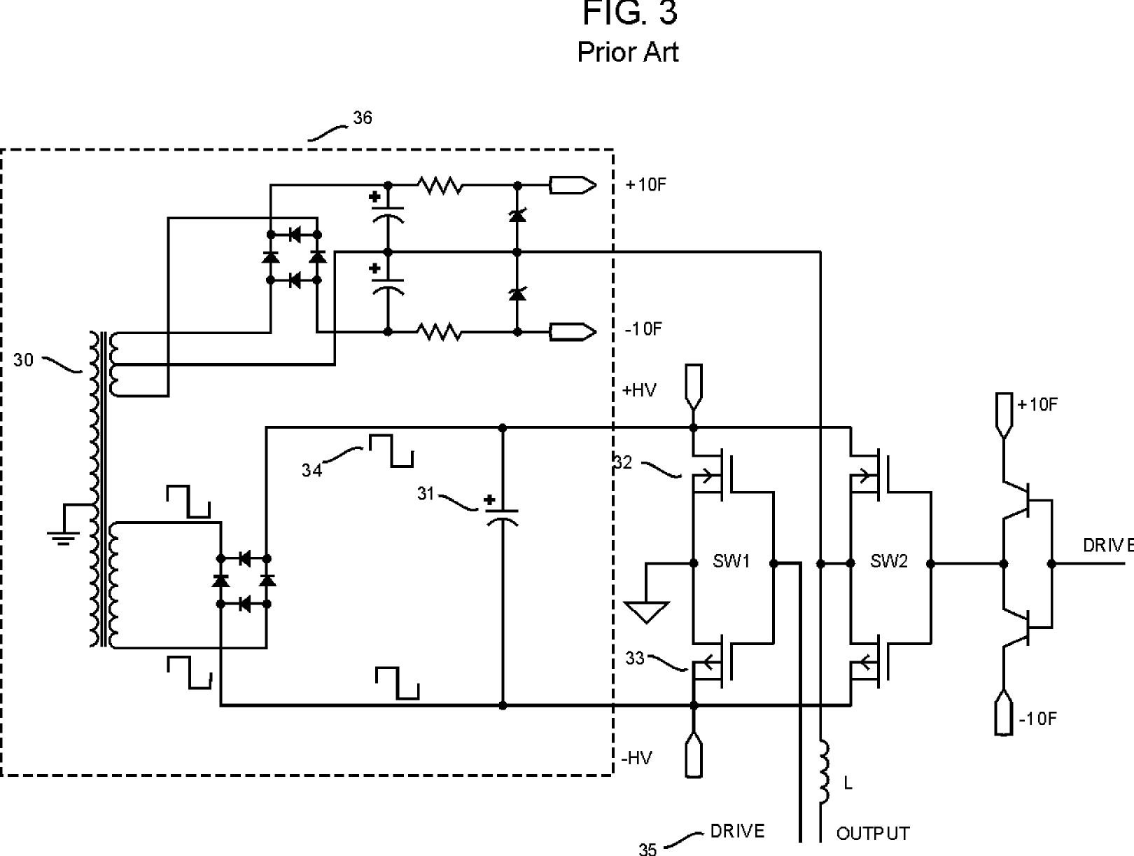

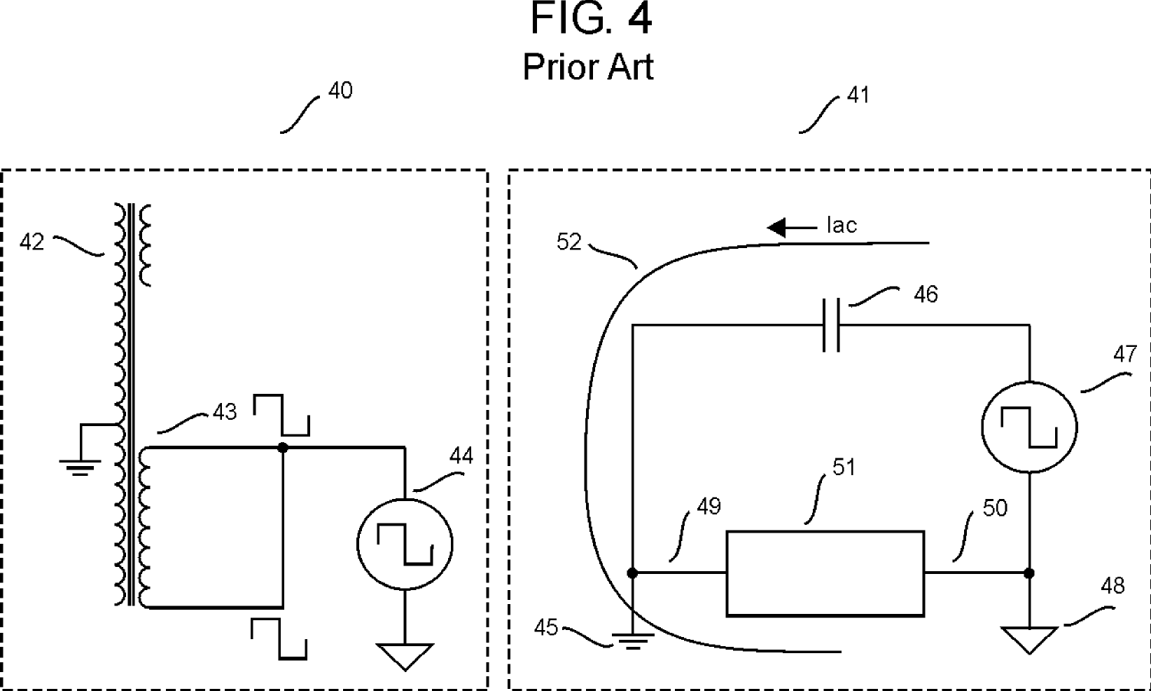

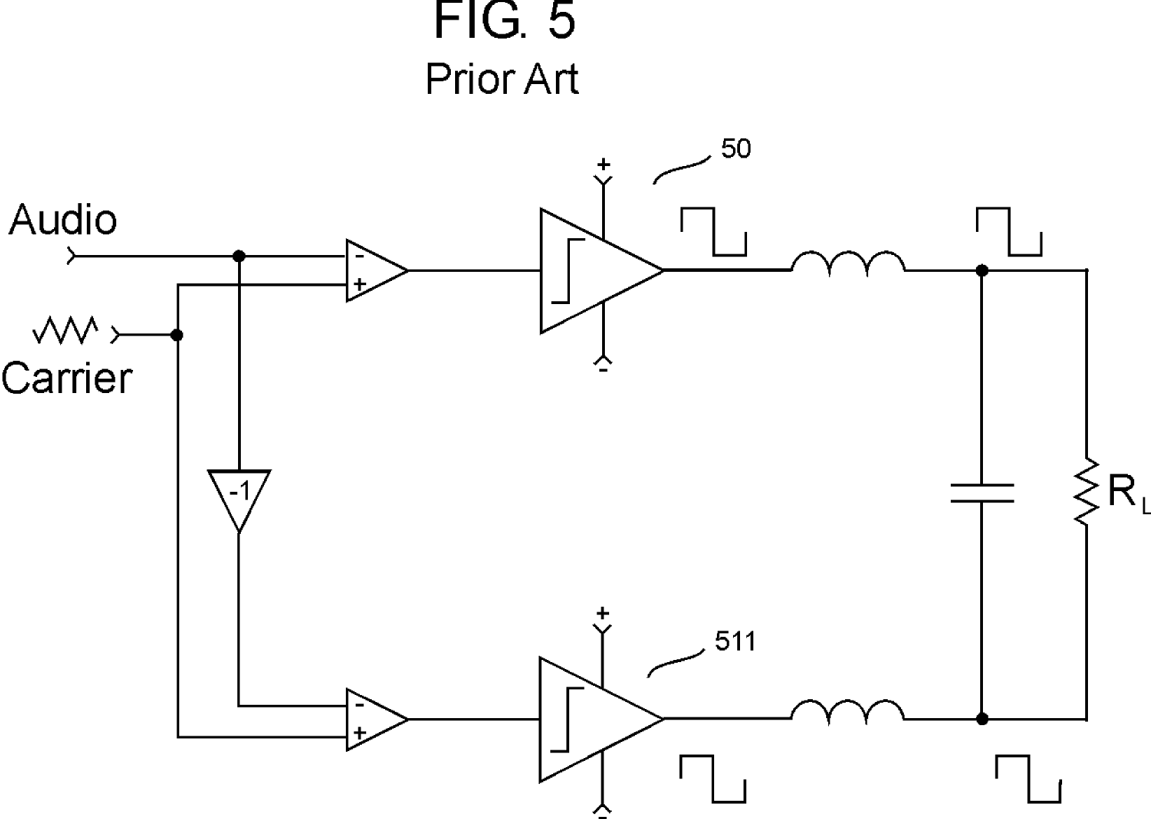

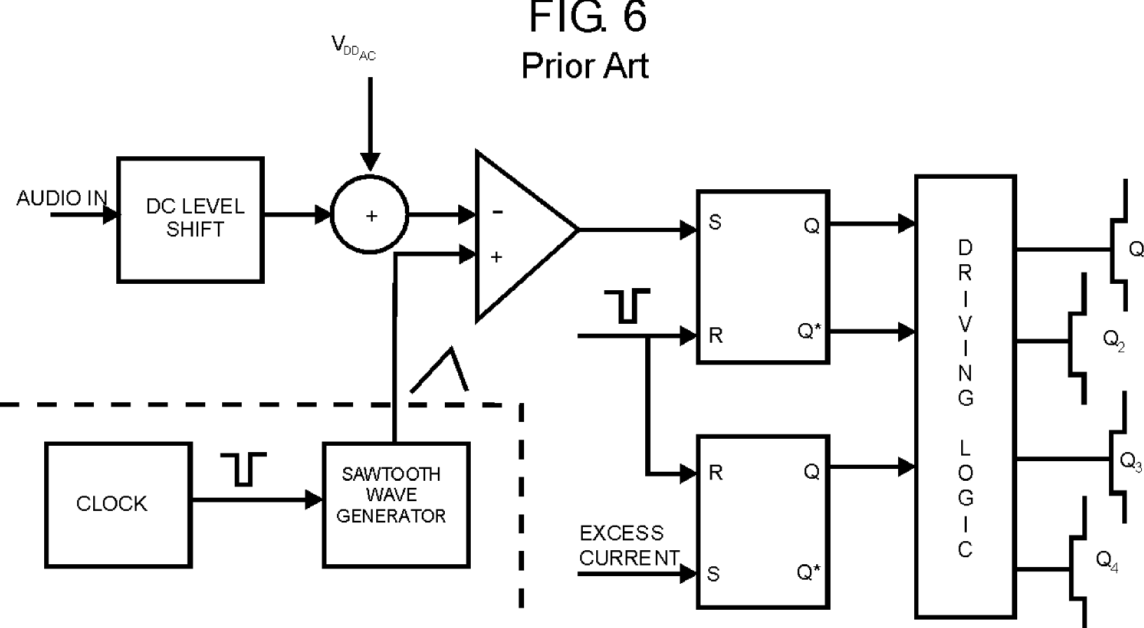

### Detailed Description

The current invention improves the prior art Class BD related to:

1. The Class BD output stage

2. Distortion introduced by supply ripple and noise

3. Notch Distortion

Improved Class BD output stage:

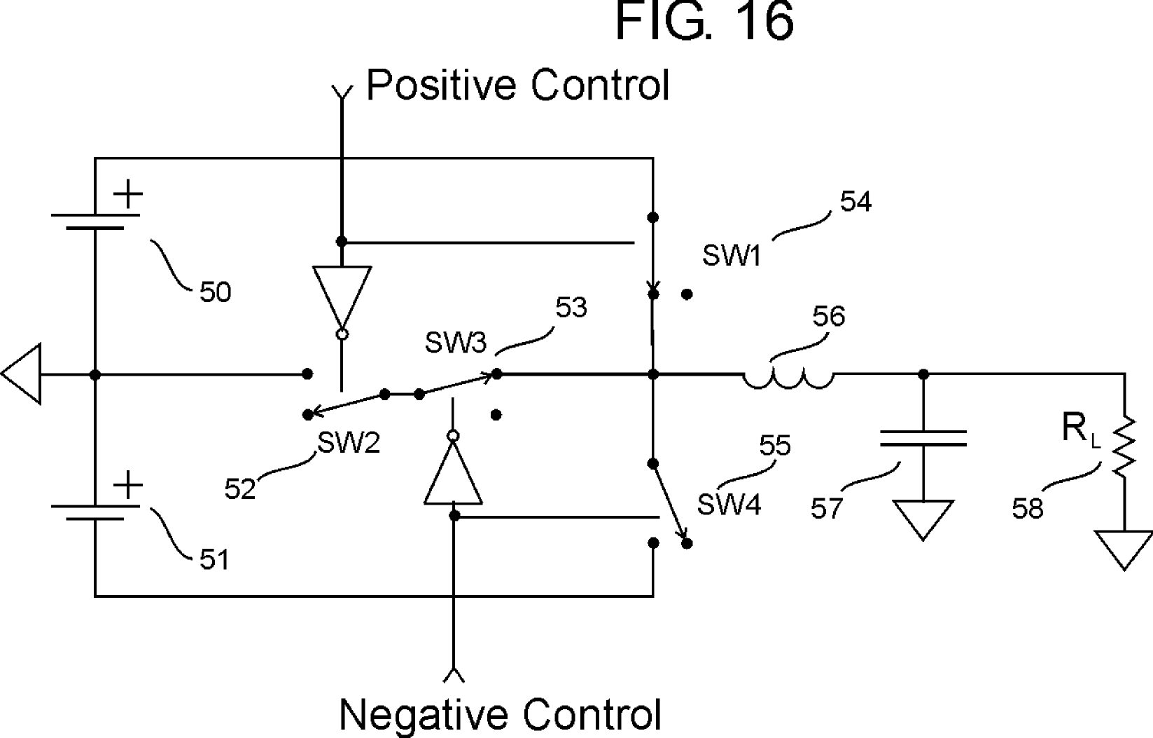

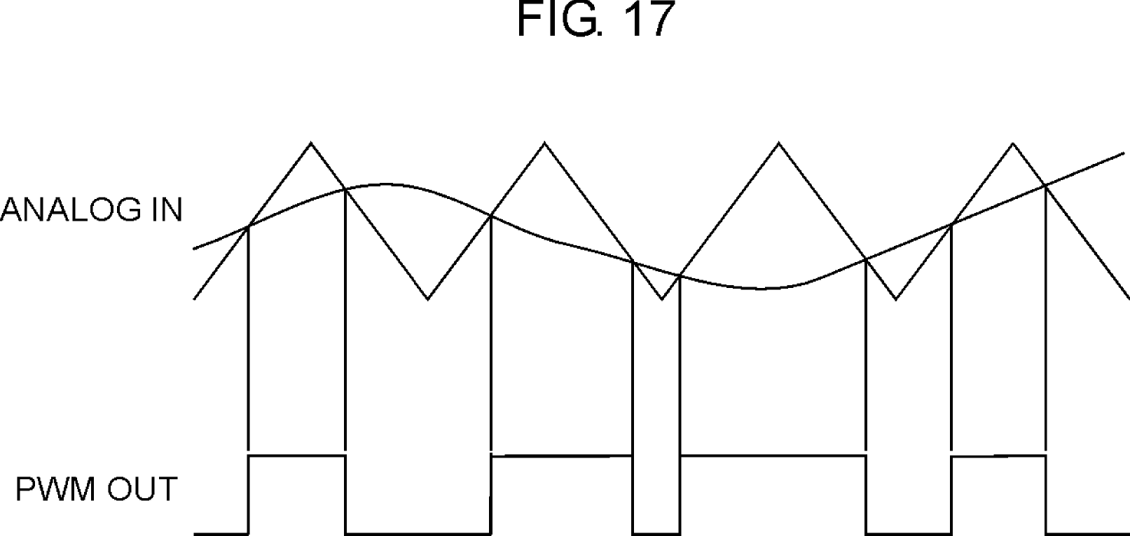

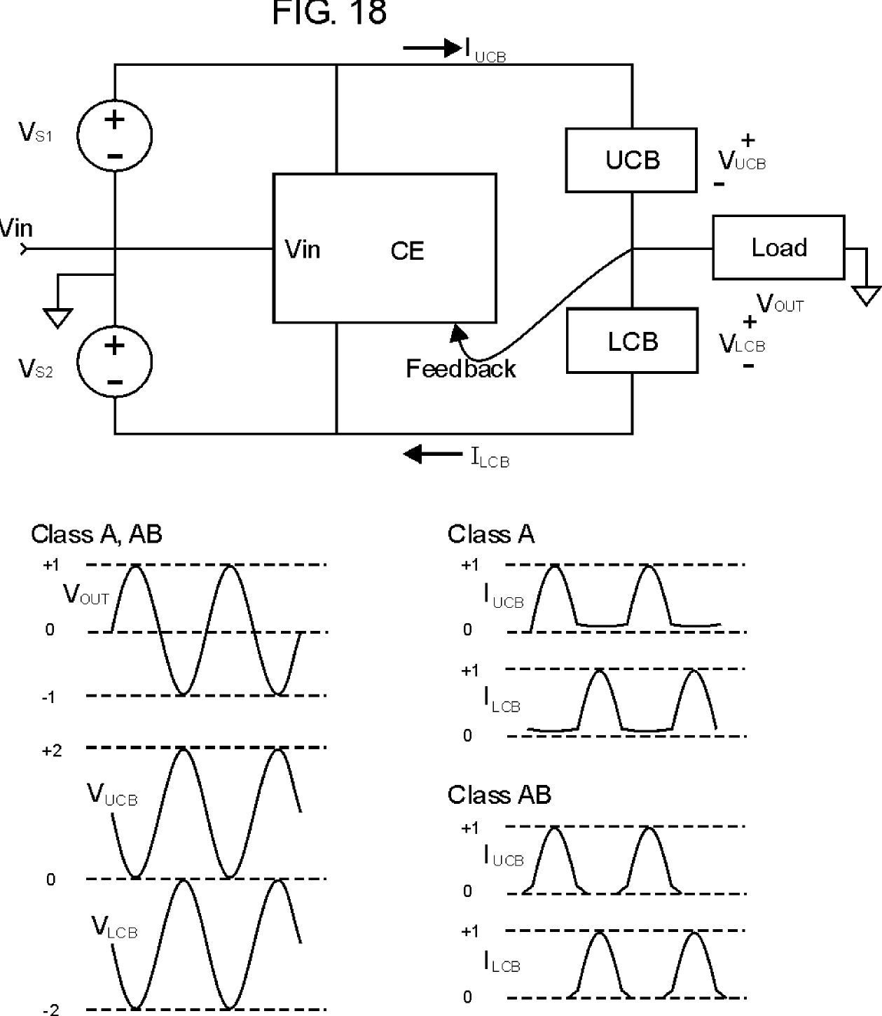

In prior art for Class BD, the output inductor current is passed through at least two switching devices. In this design, current is passed through a single switching device, except in the low power ground state. In the ground state, current is passed through two switching devices in series. (See FIG. 16) The three states are as follows:

| | | | | |
|---|---|---|---|---|
| State | SW1 (54) | SW2 (52) | SW3 (53) | SW4 (55) |
| POS | ON | OFF | ON | OFF |
| GROUND | OFF | ON | ON | OFF |
| NEG | OFF | ON | OFF | ON |

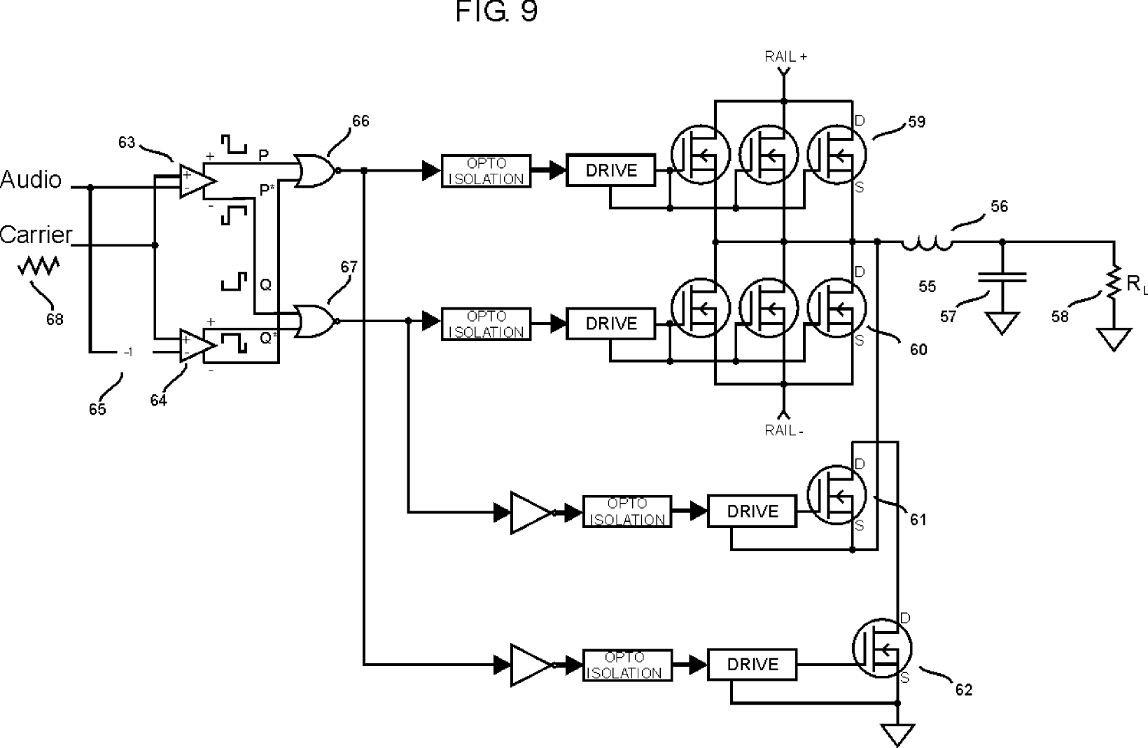

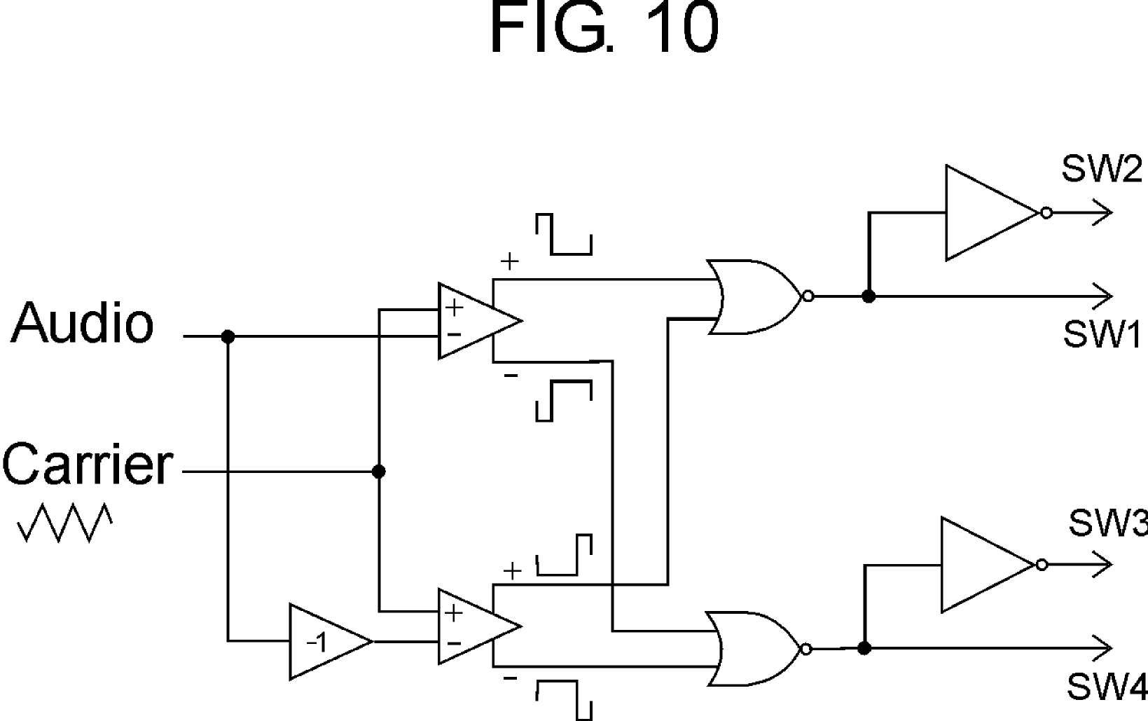

In the positive state SW3 (53) could be either on or off, likewise in the negative state SW2 (52) could be on or off. The combination illustrated above simplifies the drive circuitry, requiring just an inverter to drive each grounding state as in FIG 10. The advantage of this design is that in the positive or negative states the current passes through only one switch. The power output stage shown in FIG. 9 requires only two grounding MOSFETs because the current during this state is relatively low. While it appears that MOSFET 61 and 62 may have reverse polarity during some states, but they do not as described below.

MOSFETs pass current equally well in either direction when they are turned on. The three states are further described, keeping this attribute in mind:

Positive State: The voltage at MOSFET 61's source is positive and this device is turned on. Device 62 is turned off with a positive voltage at its drain.

Negative State: Device 61 is off with a negative voltage on its source. Device 62 is on. As can be seen all of the MOSFETs have normal voltage polarities during their off state. Their substrate diodes protect them during transitions. External diodes may be used in parallel with the inherent substrate diodes of the MOSFETs, if desired.

Drive Circuit:

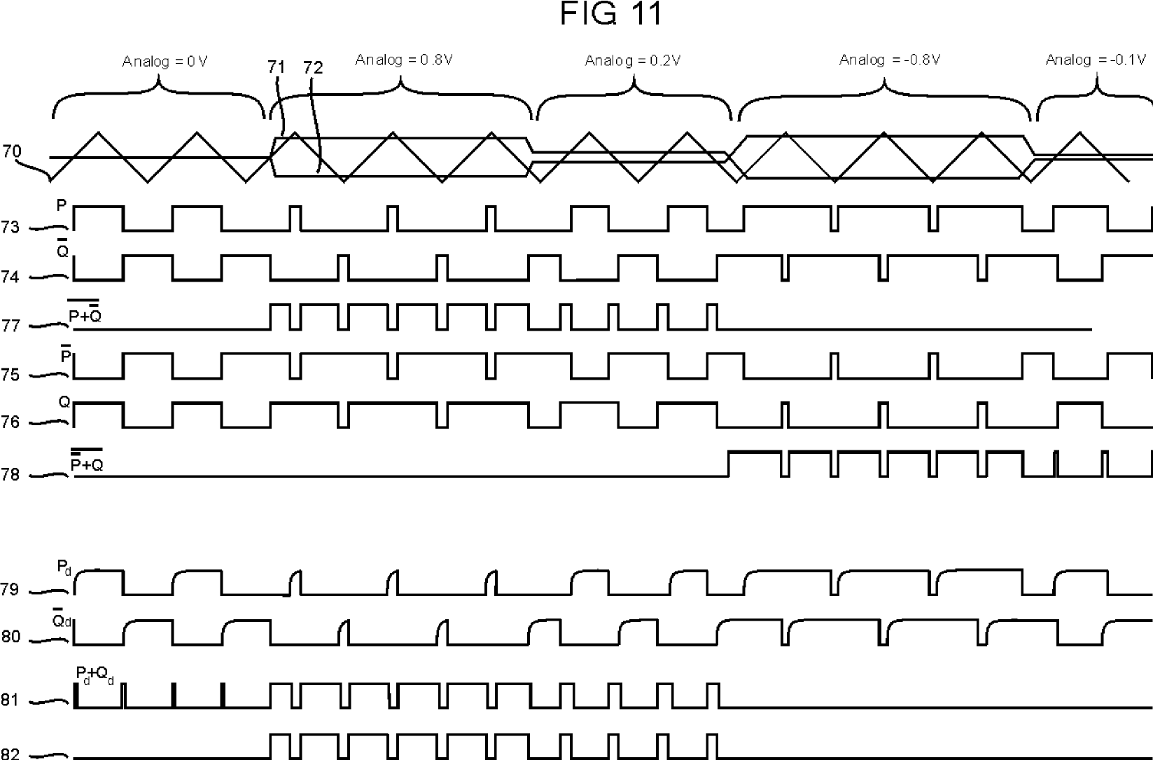

FIG. 10 shows the simplicity of the circuitry from which the MOSFET gate drives are derived in a preferred embodiment of the current invention. FIG 11 shows the associated waveforms.

FIG 9 is a block/schematic diagram of a preferred embodiment of the present invention, including MOSFET gate drive circuitry and MOSFET output device topology. A reference triangle wave 68 is applied to the inputs of two high speed comparators 63 and 64 (which may be LM161H devices or the like). In a preferred embodiment, comparators 63 and 64 have dual phase outputs. Alternatively, comparators with single phase outputs may be used, and the inverted phase may be generated by invertors. The input signal to be amplified is applied to comparator 63. The input signal is also inverted by inverter 65 and applied to comparator 64. The outputs of comparators 63 and 64 are shown in FIG. 11. The four waveforms (FIG. 11, 73-76) are P, P*, Q, and Q*. By NORing (FIG. 9, 66) P and Q* we get the Positive MOSFET drive (67). NORing (FIG. 9, 67) P* and Q we get the Negative MOSFET drive waveform, as in FIG. 11, 78. The drive for the grounding MOSFET (FIG. 9, 62) is an inverted copy of the drive for the positive MOSFET 59. The drive for the grounding MOSFET 61 is an inverted copy of the drive for the positive MOSFET 60.

Notch Distortion:

Notch distortion occurs in prior art class BD amplifier designs for input signal levels close to zero. Prior art class BD designs produce short positive pulsed for small positive inputs, short negative pulses for small negative inputs, and no pulses for sufficiently small positive or negative inputs. Lack of output pulses for very small input signals (called notch distortion) occurs because at low level signals the pulse widths the output FETs would ideally be called upon to produce are shorter than the turn on time of the MOSFETs. The current invention overcomes this problem by (for small input signals) producing short (but manageable) pulses in both the positive and negative direction. As signal amplitude gets larger in the positive direction, the negative pulses go away completely, and as signal amplitudes get larger in the negative direction, the positive pulses go away completely, but at very low signal levels, both positive and negative pulses are present, and linearly controllable in width.

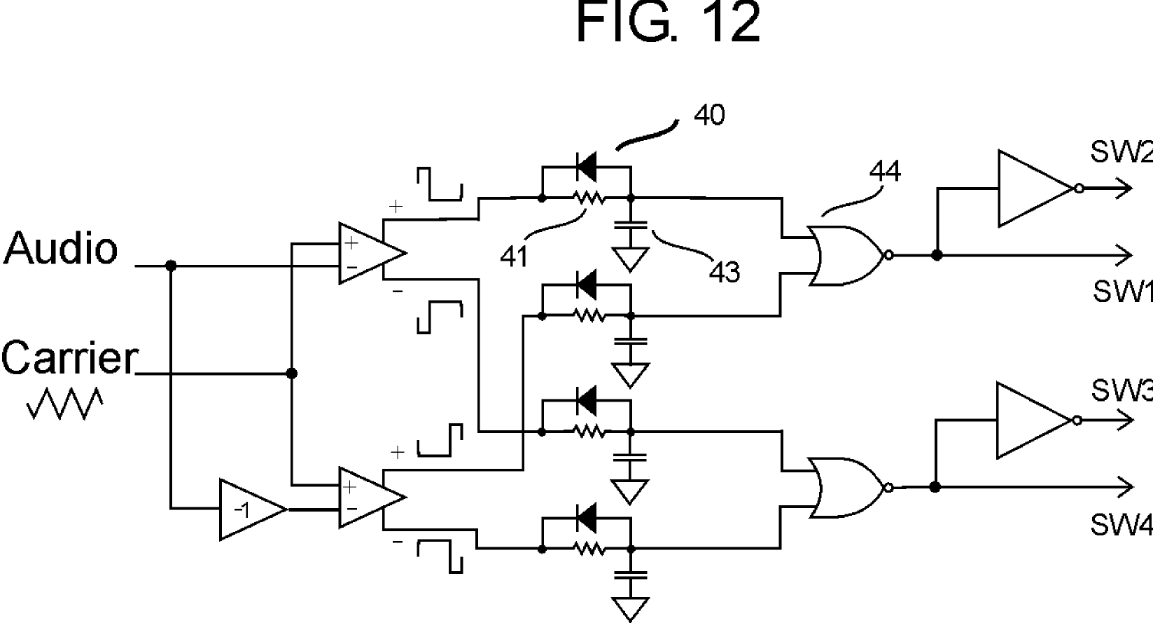

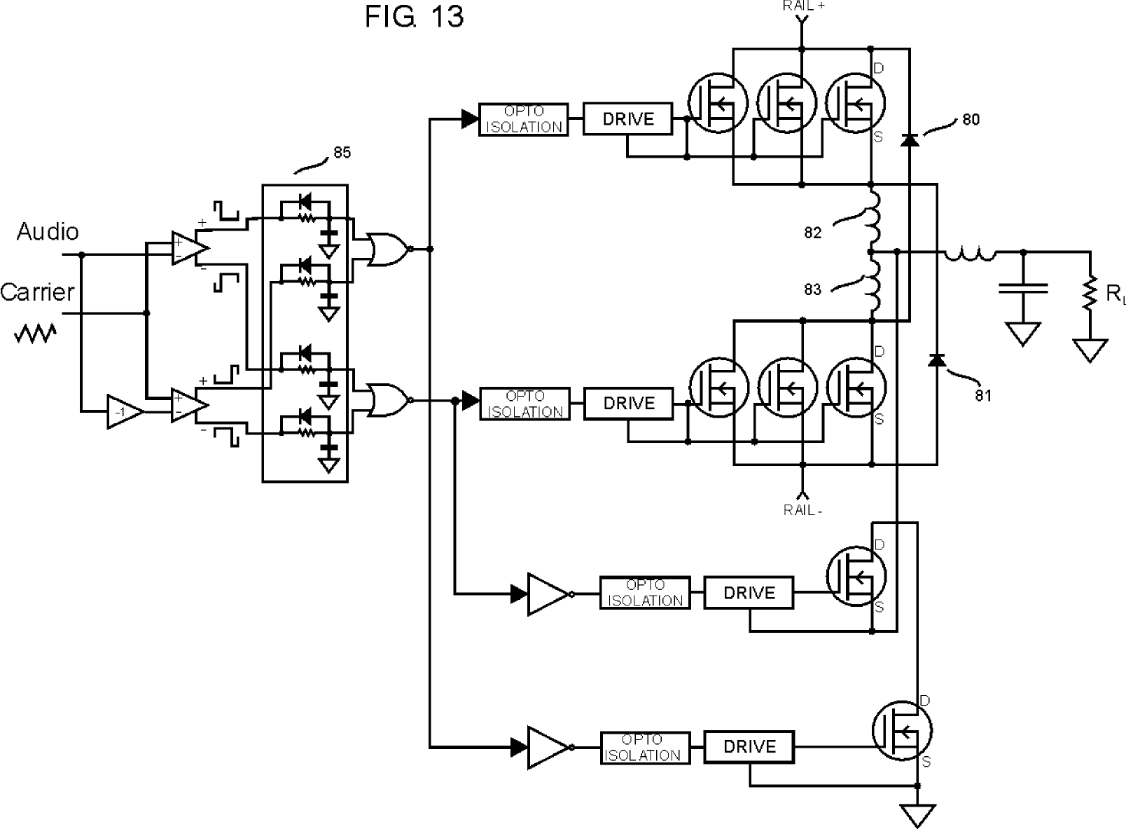

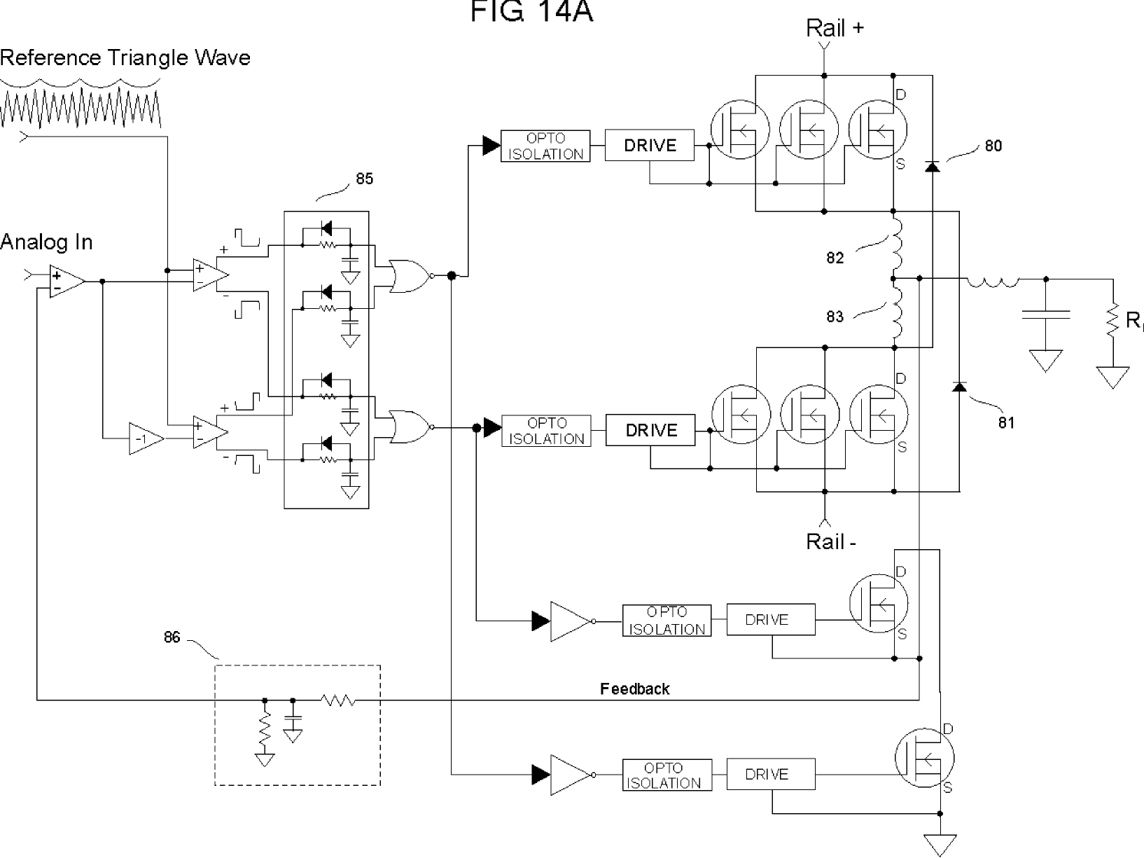

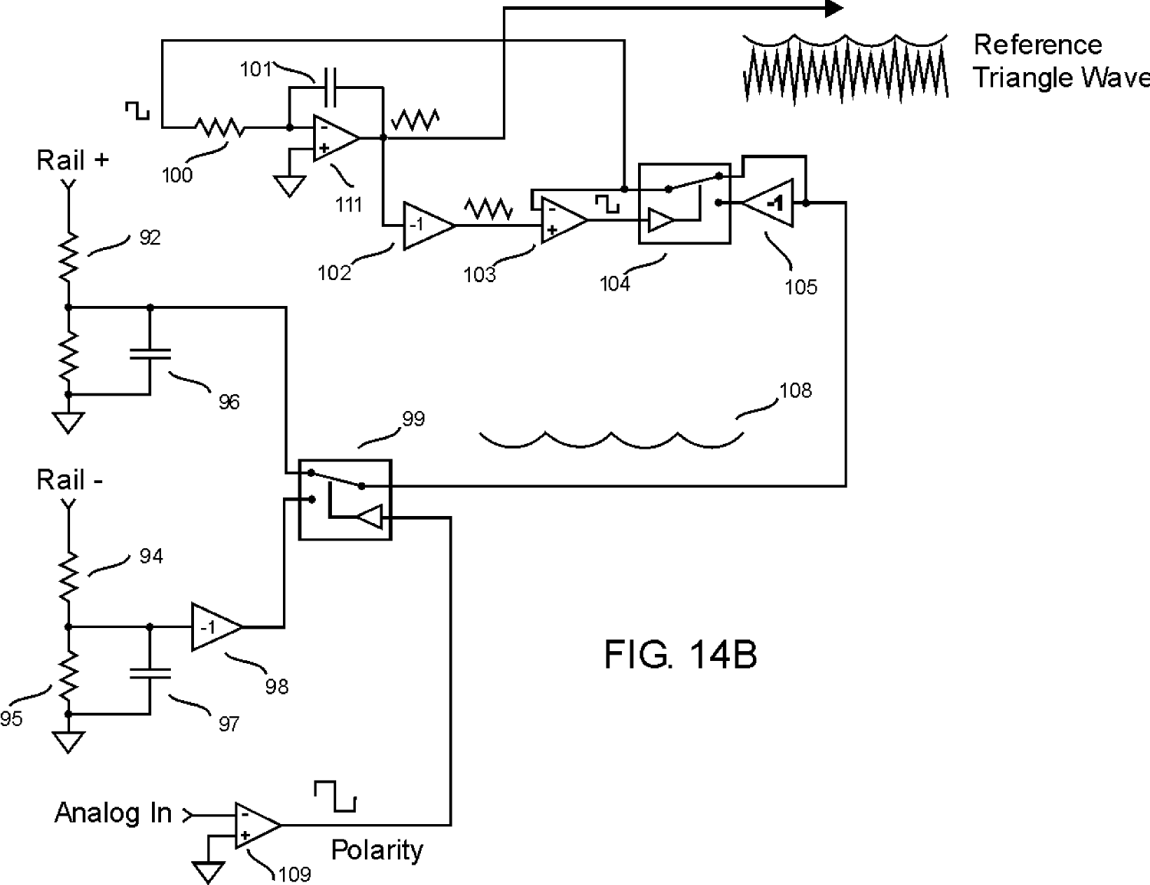

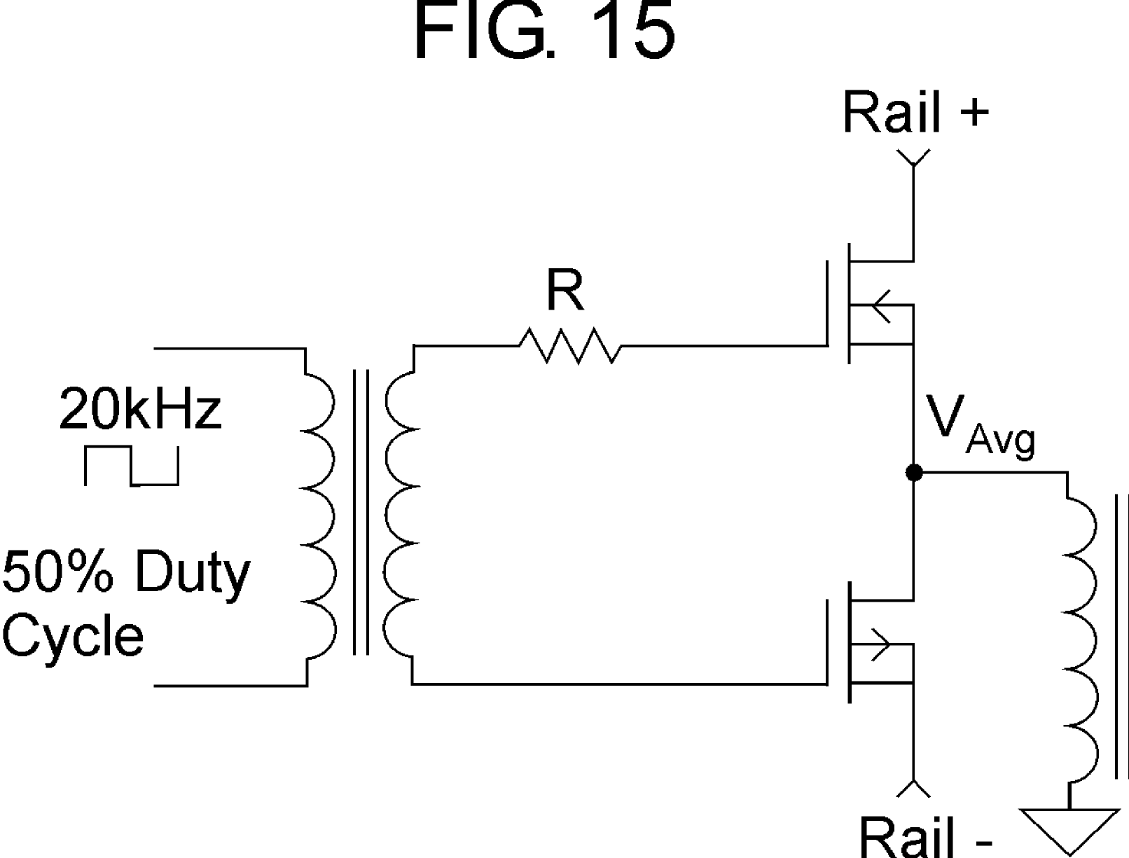

A preferred embodiment of the present invention provides linearly adjustable short positive and negative pulses simultaneously for low signal levels by stretching the gate drive pulses by delaying the input to the NOR gates as in the drive circuitry as shown in FIG. 12. The rise time of each NOR gate input (such as 44) is slowed by R-C network such as that comprised of resistor 41 and capacitor 43. In order to slow only the rise times of the NOR gate inputs, and preserve fast fall times, diodes are connected such as diode 40 to allow rapid capacitive discharge on the falling edge of the NOR gate drive waveform. The resulting waveforms are shown in FIG. 11. Waveforms 81 and 82 show the stretched gate drive for the positive and negative MOSFETs. Too much pulse stretching causes excessive common mode conduction of the output devices. In a preferred embodiment of the present invention as shown in FIG. 13, inductors 82 and 83 in conjunction with commutating diodes 80 and 81 reduce the common mode current. The preferred embodiment is shown in FIG. 14A and 14B. Notch distortion is reduced by asymmetrical delay circuit 85. In this preferred embodiment, the modulation reference triangle wave is generated as in FIG. 14B.

Power Supply Ripple

The current invention drastically reduces supply-voltage-induced distortion by making the reference waveform amplitude proportional to the supply voltage: , where K is the gain of the input stage.

$$Magnitude = K \cdot Supply Voltage \cdot \frac{Analog / N }{Carrier}$$

$$Magnitude = K \cdot Analog / N$$

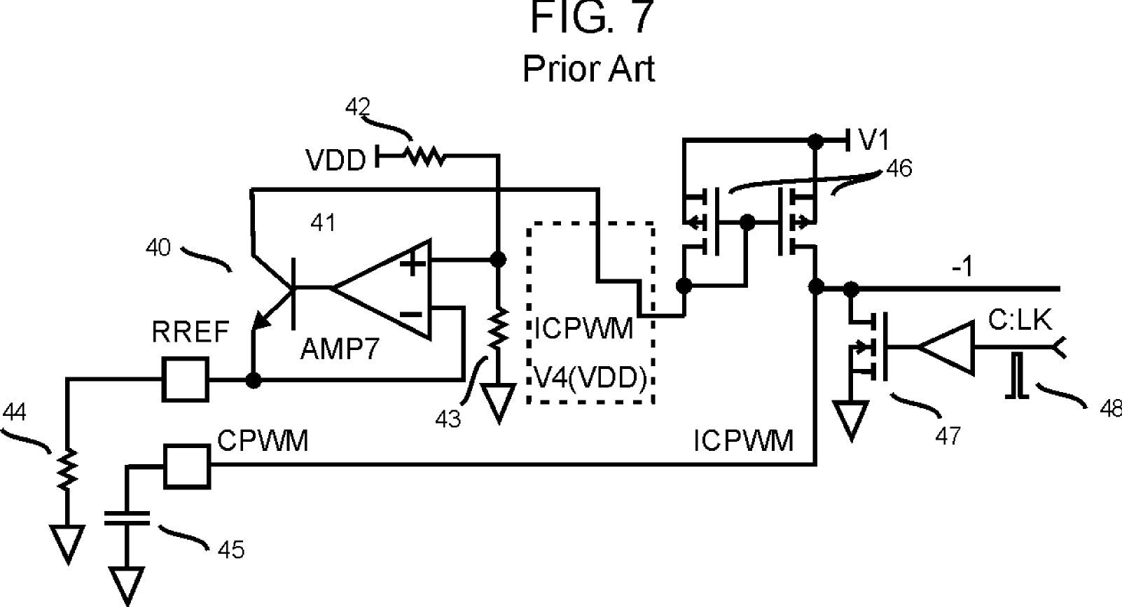

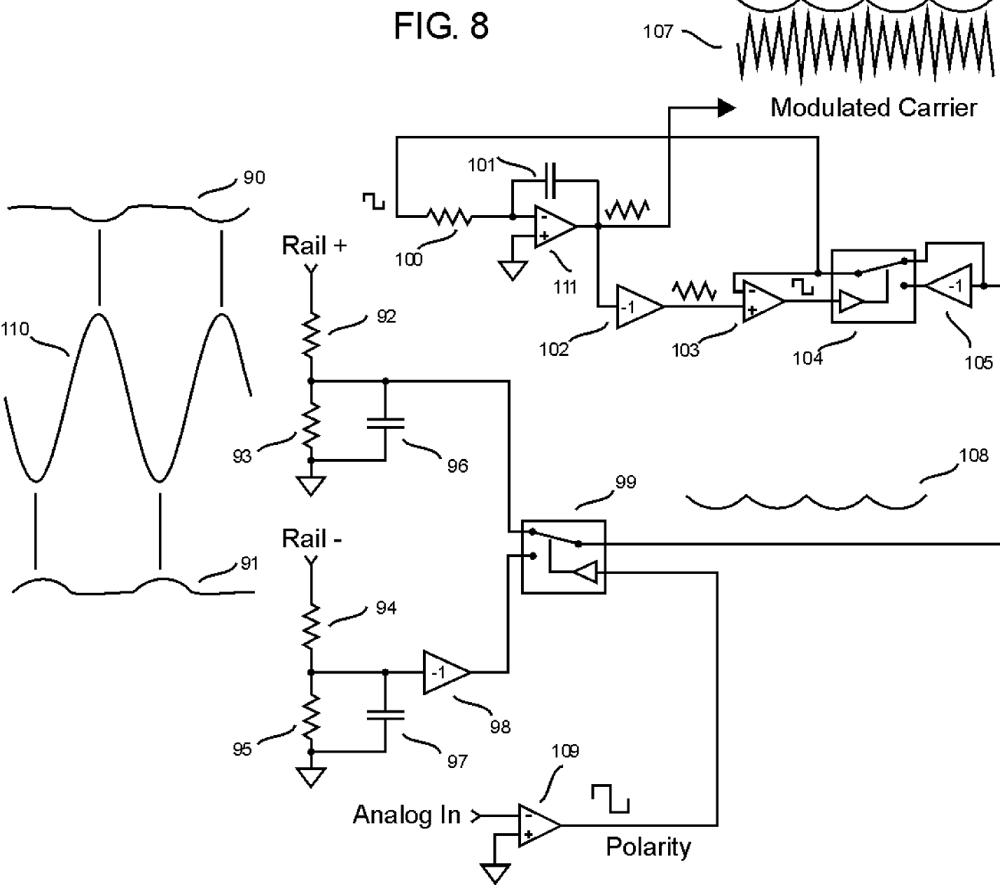

, where K' takes into account the input stage gain and the resistor dividers 92-95 of FIG. 8.

In a preferred embodiment, the modulated reference triangle wave is generated as in FIG. 8. Typical positive and negative rail ripple is depicted by 90 and 91. The positive and negative rail voltages are scaled down by resistors 92, 93, 94, and 95. Capacitors 96 and 97 filter high frequency supply switching noise, while preserving the lower-frequency "sagging" of the supplies which is synchronous with the waveform being amplified. Inverting op-amp (98) converts the scaled negative rail voltage to positive. Analog polarity detector 109 controls analog switch 99. Waveform 108 is the output of analog switch 99 and represents the supply ripple. The triangle generator is comprised of a high speed op amp 111, integrating capacitor 101, and resistor 100. Analog switch 104 generates a square wave by switching between the positive and negative reference voltages present at the input and output of the inverting circuit 105. This reference voltage varies with the magnitude of the supply. The resulting reference triangle wave is thus amplitude modulated proportional to the supply voltage. The frequency is modulated as well. For example, if the supply increases 10%, the carrier frequency (frequency of the reference triangle wave) decreases 10%. This frequency variation helps spread the EMI spectrum at high power levels. Thus, accurate power supply tracking of the reference triangle wave's magnitude results in dramatically reduced distortion and gain aberrations.

An additional problem in switching amplifiers is poor damping factor. When the amplifier's load changes, the supply voltage changes as well, depending on supply regulation. In the present invention, the reference-triangle-wave modulation circuitry stabilizes the gain of the amplifier over large changes in supply voltage, thus improving the damping factor.

Performance and testing:

The prototype of the preferred embodiment, without feedback in the audio path, had very low harmonic distortion of 0.3% for an open-loop design. Conventional negative feedback, as in FIG. 14B, 86 can be used to further reduce distortion. The prototype's carrier frequency was 200kHz, with the output frequency being 400kHz.

The foregoing discussion should be understood as illustrative and should not be considered to be limiting in any sense. While this invention has been particularly shown and described with references to preferred embodiments thereof, it will be understood by those skilled in the art that various changes in form and details may be made therein without departing from the spirit and scope of the invention as defined by the claims. Having described the invention, what is claimed is:

Claims

1. An improved Class BD three state amplifier comprising:
A. A first power supply, having a positive polarity output connected to a positive rail, and a negative polarity output connected to ground;
B. A second power supply, having a negative polarity output connected to a negative rail and a positive polarity output connected to ground;
C. An output filter;
D. A.A first electronically controllable switching device connected between said output filter and said positive rail;
E. A.A second electronically controllable switching device connected between said output filter and said negative rail;
F. Third and fourth electronically controllable switching devices, connected in series between said output and ground;
G. A.A switching control circuit for controlling said first, second, third, and fourth switching devices.

2. The amplifier of claim 1, wherein said switching control circuit has three allowed drive states for said switches, said drive states comprising:
A. A.A first state wherein said first and third switching devices are turned on and said second and fourth switching devices are turned off;
B. A.A second state wherein said second and fourth switching devices are turned on and said first and third switching devices are turned off;
C. A third state wherein said first and second switching devices are turned off and said third and fourth switching devices are turned on.

3. A reduced-notch-distortion Class BD amplifier comprising:
A. A positive modulator which produces positive pulses by pulse-switching a first output to a positive rail for all inputs signals greater than a small negative value;
B. A negative modulator which produces negative pulses by pulse-switching a second output to a negative rail for all inputs signals less than a small positive value.

4. The reduced-notch-distortion Class BD amplifier of claim 3, wherein for inputs between said small negative value and said small positive value, said positive and negative pulses are coincident in time, and further comprising first and second inductors connected in series between said positive and negative modulator outputs, forming a combined modulator output at the junction of said inductors.

5. The reduced-notch-distortion Class BD amplifier of claim 3, wherein further comprising:
A. Complementary waveform generator circuitry for generating complementary positive and negative versions of a repetitive waveform;
B. Delay circuitry with asymmetrical rise and fall time responses, for generating an asymmetrically delayed version of said positive and negative complementary repetitive waveforms;
C. Gating circuitry for performing Boolean functions on said asymmetrically delayed version of said positive and negative complementary repetitive waveforms, and controlling said positive and negative modulators.

6. An improved class BD amplifier with reduced sensitivity to supply-variation-induced distortion, comprising:
A. A first power supply, having a positive polarity output connected to a positive rail, and a negative polarity output connected to ground;
B. A.A second power supply, having a negative polarity output connected to a negative rail and a positive polarity output connected to ground;
C. A.A triangle wave generator for generating a reference triangle wave;
D. A positive modulator switching a first output to said positive rail when said reference triangle wave is positive and an input signal exceeds the value of said reference triangle wave;
E. A negative modulator for switching a second output to said negative rail when said reference triangle wave is negative and an input signal is less than the value of said reference triangle wave;
F. A.A positive triangle wave modulator for amplitude modulating said reference triangle wave proportional to the voltage of said positive rail while said reference triangle wave is positive;
G. A negative triangle wave modulator for amplitude modulating said reference triangle wave proportional to the voltage of said negative rail while said reference triangle wave is negative.
